(19) United States
(12) Patent Application Publication
(10) Pub. No.: US 2022/0399753 A1
(43) Pub. Date: Dec. 15, 2022

(54) SYSTEMS AND METHODS FOR AUTOMATED DETECTION OF SWITCH CAPACITOR OPERATION

(71) Applicant: SENTIENT TECHNOLOGY HOLDINGS, LLC, WITCHITA, KS (US)

(72) Inventors: Ye TAO, Sunnyvale, CA (US); Mirrasoul J. MOUSAVI, San Jose, CA (US)

(73) Assignee: SENTIENT TECHNOLOGY HOLDINGS, LLC, WITCHITA, KS (US)

(21) Appl. No.: 17/775,546

(22) PCT Filed: Nov. 10, 2020
(86) PCT No.: PCT/IB2020/060590

§ 371 Date: May 9, 2022

Related U.S. Application Data
(60) Provisional application No. 62/933,738, filed on Nov. 11, 2019.

(51) Int. Cl. H02J 13/00; G01R 21/00; G01R 31/64; G01R 21/133; H02J 3/18

(52) U.S. Cl. CPC H02J 13/00002; G01R 21/006; G01R 31/64; G01R 21/133; H02J 3/18; H02J 2203/10; H02J 13/00001

(57) ABSTRACT

Systems and methods herein automate detection of switched-capacitor bank operation on a power grid. At least one power line sensor (106) may be positioned on a power line to measure electric field strength and current. A processor may be in communication with the power line sensor and memory storing a capacitor bank analyzer as computer readable instructions that, when executed by the processor, control the processor to: receive electric field data and current data from the power line sensor. The processor may extract key characteristics from the electric field data and the current data, compare the key characteristics to a library of key characteristics of a predictive model, and output, based on the predictive model, a label indicating presence of, or lack of, a capacitor switching event. E-field and current data from multiple line sensors may be aggregated to provide additional insight to capacitor bank operation.

### CROSS-REFERENCE TO RELATED APPLICATION(S)

The present application claims priority to U.S. Provisional Patent Application No. 62/933,738 filed Nov. 11, 2019. The entire contents of the aforementioned provisional patent application are incorporated herein by reference.

### BACKGROUND

Intelligent line sensors and devices are increasingly used in distribution and transmission systems to enhance system monitoring and situational awareness. These devices feature different capabilities and together with operational technologies in the control room offer unprecedented opportunities for grid modernization and management of DERs (Distributed Energy Resources). Sensors with a floating voltage reference point offer cost-effective ways to capture field measurements such as e-field, line current, and conductor temperature. These sensors are equipped with on-board computer, storage, and communications making them an ideal fit for utility IoT (Internet of Things) applications at the edge of the grid. One such area of interest is switched-capacitor banks and their operational status as inferred from transients imposed on the system. Traditional transient analysis in power systems typically utilizes voltage and current waveforms. The lack of a ground reference introduces unique challenges for edge analytics in the sensor.

Capacitor banks are installed throughout the grid to offset the effect of inductive loads, which widely spread in the distribution system. Typically, a capacitive load pulls up the power factor and an inductive load pulls down the power factor in a passive network.

### SUMMARY

The embodiments herein provide systems and methods that detect capacitor bank operation. This detection allows for verification of the intended operation of the grid, such as capacitor bank energization and energization. By monitoring detected events over time, the systems and methods herein are able to verify and predict maintenance needs for the capacitor banks throughout the grid.

These determinations are able to be made based on the current and e-field data captured by smart line sensors, such as the MM3 intelligent grid sensor manufactured by Sentient Energy. The line sensors of the present systems and measurements utilize e-field measurements, as compared to other types of capacitor bank operation sensors that operate on voltage measurements. Therefore, the systems and methods provide the benefit that they do not need a reference measurement to ground, and thus require less hardware to implement the capacitor bank switching algorithms discussed herein.

In an embodiment of a first aspect, a system for automated detection of switched-capacitor bank operation on a power grid includes: a power line sensor positioned on a power line to measure electric field strength and current; a processor in communication with the power line sensor; and memory storing a capacitor bank analyzer as computer readable instructions. When the capacitor bank analyzer is executed by the processor, the processor is controlled to: receive electric field data and current data from the power line sensor; extract key characteristics from the electric field data and the current data; compare the key characteristics to a library of key characteristics of a predictive model; and output, based on the predictive model, a label indicating presence of, or lack of, a capacitor switching event.

In an embodiment of a second aspect, a method for verifying the operation of capacitor bank on a power line includes: sensing, using a power line sensor, current and electric field on a power line; recording a transient waveform based on the sensed current and electric field; determining key characteristics of waveform; comparing the key characteristics with a library of recorded characteristics to generate a label of a transient event within the transient waveform; and outputting the label.

In an embodiment of a third aspect, method for correlating sensed capacitor bank switching events by a plurality of line sensors, including: labeling a transient event in a waveform sensed by a first line sensor of the plurality of line sensors; determine if at least one capacitor bank nearby the first line sensor is capable of producing the transient event; and when at least one capacitor bank is nearby the first line sensor identify at least one other line sensor of the plurality of line sensors within a proximity to the at least one capacitor; for each other line sensor: analyze another waveform received by the other line sensor, to identify a potential sympathetic event, and flag the potential sympathetic event as a sympathetic event when the potential sympathetic event correlates to the transient event.

### BRIEF DESCRIPTION OF THE FIGURES

The foregoing and other features and advantages of the disclosure will be apparent from the more particular description of the embodiments, as illustrated in the accompanying drawings, in which like reference characters refer to the same parts throughout the different figures. The drawings are not necessarily to scale, emphasis instead being placed upon illustrating the principles of the disclosure.

FIG. 1 depicts an example system of sensors and a processor to detect switched-capacitor bank operation, in embodiments.

FIG. 2 depicts a block diagram of a line sensor, which is an example of the line sensor of FIG. 1, in embodiments.

FIG. 3 depicts a block diagram of a processor, which is an example of the processor of FIG. 1, in embodiments.

FIG. 4 depicts a diagram of the server processor memory map.

FIG. 5 depicts a flow chart of the capacitor bank classification.

FIG. 6 depicts a flow chart of a capacitor classification model development.

FIG. 7 shows example waveform data of the three-phase real/reactive power and power factor of a capacitor bank energization as measured by a sensor that is upstream from the capacitor bank that is energizing.

FIG. 8 shows example waveform data of the three-phase real/reactive power and power factor of a capacitor bank energization as measured by a sensor that is downstream from the capacitor bank that is energizing.

FIG. 9 shows a load change transient by an upstream sensor.

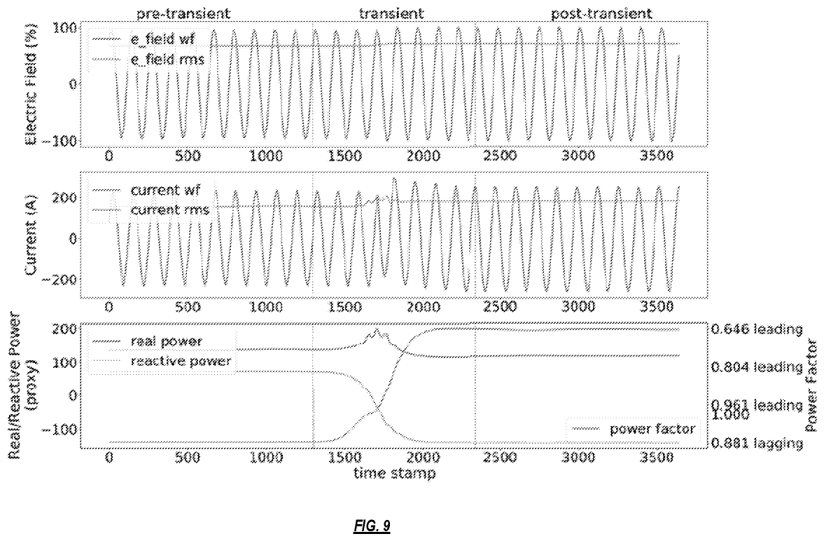

FIG. 10 Feeder capacitor bank energization as reported across three sites.

FIG. 11 shows two sets of (proxy) real/reactive power and power factor graphs from two sensors capturing a substation capacitor bank energization event.

FIG. 12 shows a block diagram of a process that identifies sympathetic capacitor switching events

FIG. 13 shows a method for comparing multiple phases of a single transient event.

FIG. 14 shows a method for monitoring and managing historical operation of switched-capacitor banks in a grid.

### DETAILED DESCRIPTION OF THE EMBODIMENTS

The systems and methods described herein acknowledge that identifying capacitor bank operation waveforms in the field helps the utility track the health status and the performance of the capacitor bank at the field point of view. A capacitor bank typically has four operational statuses: 3-phase normal operation, 1 phase broken, 2 phases broken, and total failure. The systems and methods herein provide a field capacitor bank classifier with aggregation that is able to track these three cases by comparing the operational events in A, B and C phases.

A capacitor bank normally has 6 or 12 steps to enable control in steps. In some circumstances, the operator (using a SCADA system) may set a capacitor bank to a certain step for all phases and control energizing and de-energizing. This control may occur in a predetermined time stamp in each day or when power factor drops to some level. Since the amount of capacitor bank engagement in each phase is known (such as via information in a SCADA system), the systems and methods herein are able to validate whether the actual reactive power introduced by the switched-capacitor bank and the preset value are consistent. If the actual reactive power reduction is relatively low compared with the preset step, the switched-capacitor bank may be degraded, which can help the utility identify the switched-capacitor banks not fully functional.

Since the preset reactive power energizing of a capacitor bank may not be adjusted timely, the feeder may be over compensated or under compensated. That is, the power factor after capacitor bank switch in may be still lower than 0.9 or going to leading. The e-field based power factor as a byproduct of the systems and methods herein may know the actual power factor before and after the switching. Therefore, utilizing the operational label of a given switched-capacitor bank, as generated by the systems and methods herein, an operating utility may adjust the setting if the capacity is adequate or add more capacitor banks if inadequate.

Traditionally, the capacitor bank event identification and the power factor are based on the voltage and current. The systems and methods herein acknowledge that since voltage measurement requires grounding, utilities usually install e-field based sensors. However, e-field measurement may not fully reflect the actual voltage due to the interference from the environment and cross talk with other phases. In addition, current switched-capacitor bank waveform classification algorithms rely on the measurement close by, but the line sensor may be hundreds of meters away from the corresponding capacitor bank. Different with existing capacitor bank classifier applications, the waveforms labelled as non-capacitor bank cases will be transferred to the aggregator for further analysis. Ordinary capacitor bank cases may be deleted in the field and only metadata will be transferred to save the communication bandwidth.

The present systems and methods resolve these grounding, spatial proximity, and various e-field influence problems by utilizing a machine-learning algorithm to analyze as many potential waveforms as possible. The use of a machine-learning classifier enables analysis and identification of capacitor bank operational status that is otherwise not perceptible to human, or standard key-characteristic analysis. For example, a given waveform characteristic may indicate a certain operational status, but such a key-characteristic is actually caused by an external influence on the e-field. The machine-learning algorithm(s) discussed herein account for such external influence and provide a more accurate analysis, thereby reducing false-positives and false-negatives.

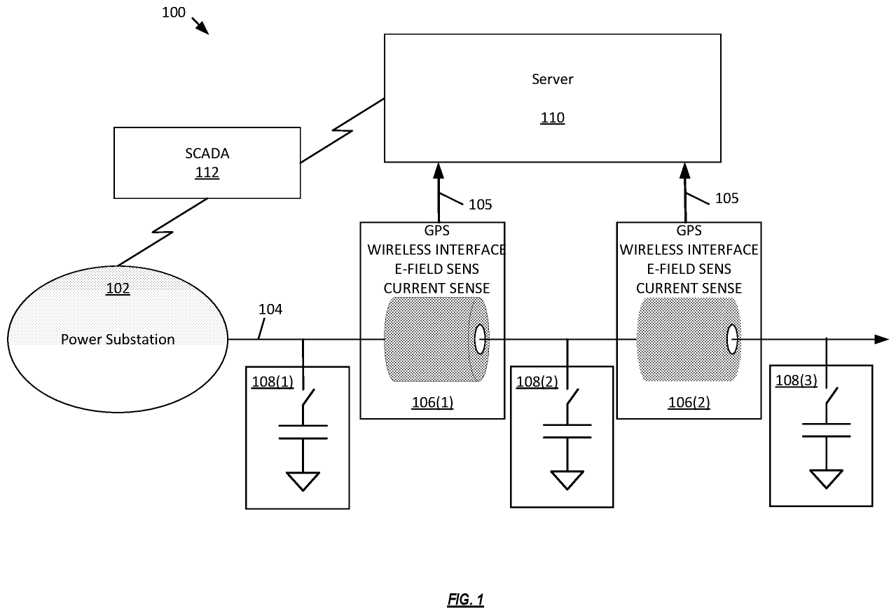

FIG. 1 depicts an example of a system 100 with one or more capacitor bank operational sensors used to detect operation of a capacitor switch bank, in embodiments. System 100 includes a Power Substation 102 that process power for a utility as either transmission or distribution station. Said power is distributed along power line 104, which may include three phases, namely Phase A, Phase B, and Phase C. At least one line sensor 106 is placed along the power lines and are generally placed on each phase of the power lines. Each instance of line sensor 106 may include three sensors, one each of Phase A, Phase B, and Phase C of line 104.

FIG. 1 shows two sets of sensors 106(1), 106(2) placed at different locations along the power line. System 100 is also shown including switch-capacitor banks 108 shown at various places along the power line. FIG. 1 shows three switched-capacitor banks 108(1)-(3), but more or fewer may be included in the system 100 without departing from the scope hereof. The first switched-capacitor bank 108(1) is placed closer to the substation than each of the line sensors 106(1) and 106(2), such that the power is flowing from first switched-capacitor bank 108(1) through the sensors. Accordingly, first switched-capacitor bank 108(1) is referred to as the upstream switched-capacitor bank. The second switched-capacitor bank 108(2) is the mid-stream capacitor bank in the example of FIG. 1, since it appears between the first line sensor 106(1) and the second line sensor 106(2). The third switched-capacitor bank 108(3) is referred to as a downstream capacitor bank.

Each line sensor 106 includes an electric field sensor, a current sensor and a GPS interface to attach an accurate time stamp and location to the data as it is collected. A non-limiting example of line sensor 106 is the MM3 intelligent grid sensor manufactured by Sentient Energy. Each line sensor 106 may also contain a wireless interface 105 so that it can telemeter the data to a back-end server 110, or the cloud, for evaluation and processing. The term back-end server is used to represent any external processing that is wirelessly connected to the sensors for processing and evaluating data. The sensor 106 can send either real time data where it sends samples of electric field data, current data, and GPS position and time stamps to a back-end server 110 as a representation of the time signals to the back-end server 110 or cloud directly. The sensors 106 can also send a reduced data set that is preprocessed by identifying characteristics or markers and send those thereby reducing the amount of data that is required to be transmitted. This metadata is then sent to the back-end server 110 or cloud for switched-capacitor bank operation classification. There is also a back-end server 110 that communicates with the sensors 106 via a wireless interface. The server 110 looks at and evaluates current, electric field, and GPS data to determine operation of the switched-capacitor bank(s) 108 and stores data in the processors' memory. A GPS time stamp helps synchronize the measurements and be used to evaluate multiple sensors data and can evaluate switch-capacitor operation from sensors that are upstream and sensors that are downstream. Knowing the GPS location and line loading for each sensor determines where in the grid array of sensors each sensor is located and how far it is from a particular switch-capacitor bank allowing the synchronized data sets to be correlated and used to determine successful execution of a particular switch-capacitor operation. These data sets can also be used to develop the learning algorithms for sensors that may be further removed for a capacitor bank as well as identify sympathetic switch capacitor operation, or in other words, determining transients at multiple sets of sensors identifying the same capacitor switch operation. The processor can then use a machine learning algorithm to determine operation of one or more switched-capacitor bank.

Each switched-capacitor bank 108 (also referred to as a capacitor bank) includes one or more capacitors coupled in series or in parallel that are used for shunting and power-factor correction in the power grid.

The functions of the back-end server 110 can also be performed by the sensors 106 themselves. By transmitting their data to the other sensors, they can each evaluate the sets of waveforms and determine the state or action of a capacitor bank. Thus, the function of the back-end server 110 can be performed in a distributed processing manner among a set of line sensors and their associated processors.

There are a number of states that can be determined about the switched-capacitor bank. It can determine that the switches closed and the switched-capacitor bank is working properly. It can also determine that the switch has opened and is operating correctly. It may also determine that the switch closed and is not working appropriately. For example, it may determine that the switch closed but not all three phases are appropriately engaged, or by contrast it may determine that the switch opened and one phase remained at least partially connected. The data from a set of sensors may also determine that a capacitor bank upstream is operating correctly or that a capacitor bank downstream is operating correctly. Thus, according to the operating modes and the measurement points, capacitor bank waveforms can be classified into at least four categories: energizing upstream of a sensor providing a given dataset, energizing downstream of the sensor, de-energizing upstream of the sensor, and de-energizing downstream of the sensor.

The states of the switched-capacitor bank(s) 108 may be transmitted to a SCADA system 112, for analysis and operational control based thereon. Information from the SCADA 112 may further be utilized to verify operation of the system 100, such as by comparing determined states of the switched-capacitor bank(s) 108 to control signals concerning the switched-capacitor bank(s) 108 from the SCADA 112.

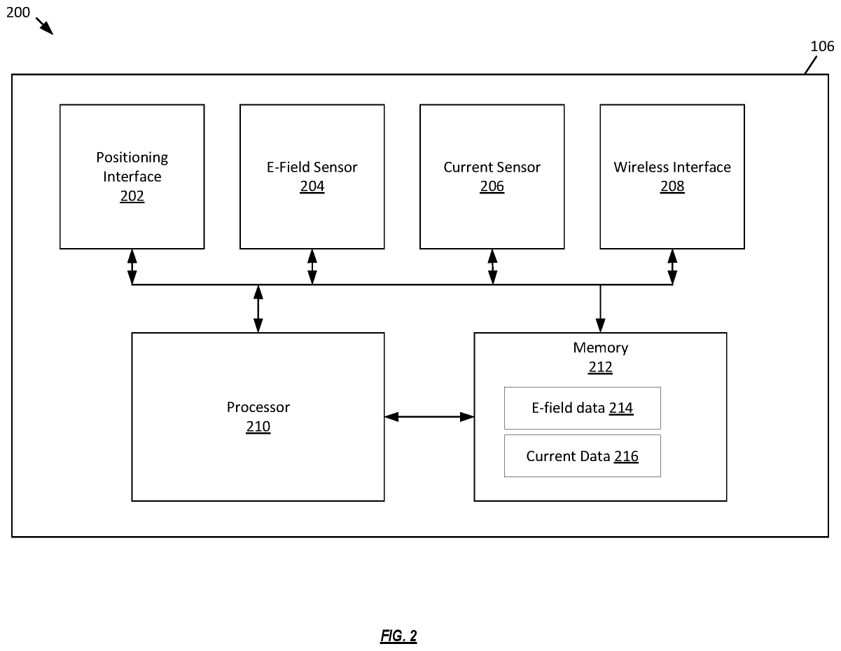

FIG. 2 depicts a block diagram 200 of an example of the line sensor 106, of FIG. 1, in further details, in embodiments. Line sensor 106 includes a Positioning Interface 202; an Electric Field, or E-Field, sensor 204; a current sensor 206; a wireless interface 208; a processor 210; and memory 212. As discussed above, each sensor 106 in FIG. 1 may represent three sensors. The block diagram of FIG. 2 shows one of these sensors. Thus, for each instance 106 in FIG. 1, there may be an individual instance of the block diagram 200. Each set of sensors represented by numeral 106 in FIG. 1 may share components of the block diagram 200. For example, there may be a single instance of GPS interface 202, Wireless interface 208, processor 210 and memory 212 for a set of three E-Field sensors 204, and a set of three current sensors 206 that are each physically located on a respective phase of line 104.

The positioning interface 202 includes location-gathering circuitry, such as, but not limited to: GPS, GLONAS, BeiDou, QZSS, IRNSS, NavIC, cellular-triangluation, etc. The positioning interface 202 captures accurate time and location stamps, which are stored in the memory 212.

The E-field sensor 204 measures the electric field strength in close proximity to the power line 104. The E-field is produced by the presence of voltage on a charged conductor of the power line 104, regardless of the current. The value measured can be affected all voltage sources around the conductor. In a three-phase AC system, there is a cross-coupling effect from the nearby phases of the power line 104. In other words, the voltage in an adjacent phase can affect the measurement is a particular phase. In addition, the earth is viewed as a natural e-field which superimposes components on top of the line e-field produced in the grid. Fluctuations in the dielectric constant or relative permittivity between the power line and the earth is another source that affects the E-Field measurement by the E-field sensor 204 and has to do with the environmental conditions surrounding the sensors.

The current sensor 206 measures current through the line 104. The current sensor 206 may include a current transformer to measure the current on line 104. The current measurements can be paired with the e-field sensor to determine the power factor. The power factor is determined by the angle between the voltage and current. At a unity power factor, or a power factor of one, the voltage and current are in phase with each other. Unity power factor gives the maximum real power transfer. With an overall inductive load, the voltage leads the current i.e. leading power factor. A capacitor bank, such as any capacitor bank 108 of FIG. 1, is connected to the power line 104 to offset the inductive characteristics caused by loads occurring throughout the power grid.

As discussed above, the position interface 202 enables time and location stamping such that the e-field and current data captured by e-field sensor 202 and current sensor 206, respectively, can be stored in memory along with a location and time stamp. In particular, the position interface 202 provides time accuracy up to few microseconds. Thus e-field and current data can be time stamped and placed at a particular sensor so that their information may be correlated. The data in the memory 212 may then be communicated with a server 110 a wireless interface 208.

The processor 210 may be any computing device capable of executing non-transitory computer readable instructions. The memory 212 may be any data storage device capable of storing the e-field data 214 and current data 216 from the e-field sensor 204 and current sensor 206, respectively, which may include location and time stamps from the position interface 202. The memory 212 may further store computer readable instructions that, when executed by the processor 210, implement the functionality of the line sensor 106 discussed herein.

The wireless interface 208 may include hardware and software capable of implementing a wireless protocol including, but not limited to, WiFi, cellular connections (e.g., GSM, GPRS, EDGE, UMTS, HSPA, CDMA, SMS, 2G, 3G, 4G, 5G, NB-IoT, LPWAN, etc.). In certain cases, the wireless interface 208 may include a wired interface as opposed to a wireless protocol.

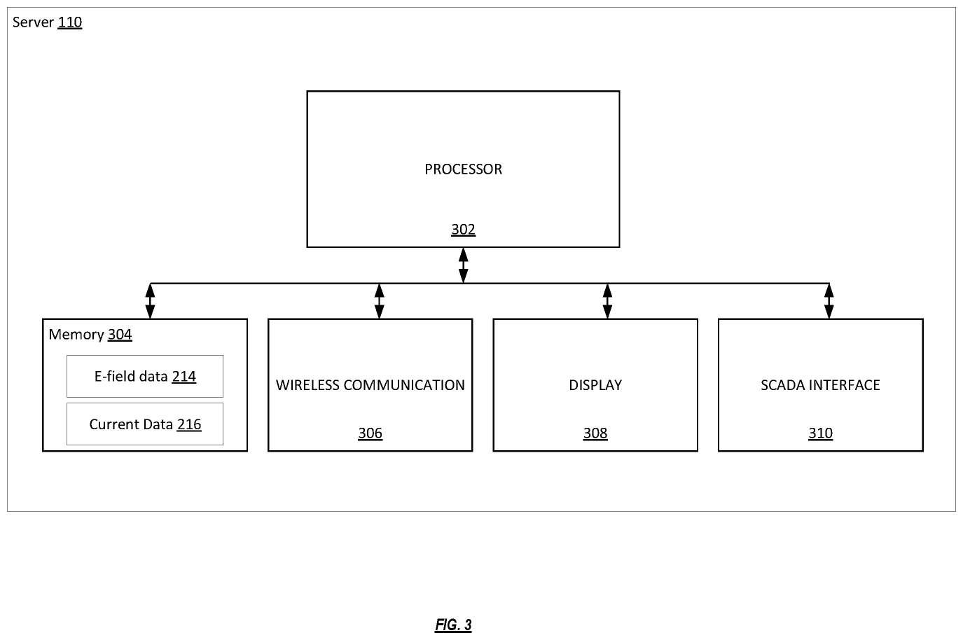

FIG. 3 is a block diagram 300 of the server 110 of FIG. 1, in embodiments. The server 110 may represent one or more computing devices. The server 110 may be a dedicated computing device, such as a local computing device that is owned and stored locally at an on-site location of the grid. Alternatively, the server 110 may represent “cloud” computing where data is transmitted thereto for processing by one or more cloud-computing services, such as Microsoft Azure, Amazon AWS, Google Cloud, etc. Server 110 includes a processor, or intelligent controller 302 connected to a memory 304 a wireless communication interface 304 a possible display 308 that can be used by an operator, and a SCADA interface 310. The SCADA interface 310 may be a component of the wireless communication interface 306, in which data from the server 110 is transmitted to SCADA 112 off-site from the server 110. Furthermore, the display 308 may be external to the server 112 as well, where the data from server 110 is transmitted to an external device (e.g., the SCADA 112 and/or an operational device associated with power substation 102, and/or a remote device such as a phone, tablet or computer used by a power-system operator) and used to display a validated operation of the switched-capacitor bank.

Server 110 receives the e-field data 214 and the current data 216 from each of the line sensors 106 via the wireless communication interface 306. The wireless communication interface 306 may include hardware and software capable of implementing a wireless protocol including, but not limited to, WiFi, cellular connections (e.g., GSM, GPRS, EDGE, UMTS, HSPA, CDMA, SMS, 2G, 3G, 4G, 5G, NB-IoT, LPWAN, etc.). In certain cases, the wireless interface 208 may include a wired interface as opposed to a wireless protocol. The e-field data 214 and the current data 216 received from the sensors 106 through the wireless interface 308 may be the raw data captured by the e-field sensor 204, and current sensor 206, respectively, or may be preprocessed string of data consisting of metadata. The received data may or may not be presented on the display 308 and/or SCADA interface 310.

The received e-field data 214 and current data 216, as well as the location and time stamps from the positioning interface 202 associated therewith may be stored in the memory 304. The memory 304 may further include computer readable instructions that, when executed by the processor 302 implement the functionality of the server 110 discussed herein. For example, the processor 302, upon execution of the instructions within memory 304, may also reduce or process the e-field data 214 and current data 216 to identify and classify key characteristics of the signal waveforms defined thereby. Using these key characteristics, the processor 302 may identify that an event has occurred and, if the data allows, classify the event.

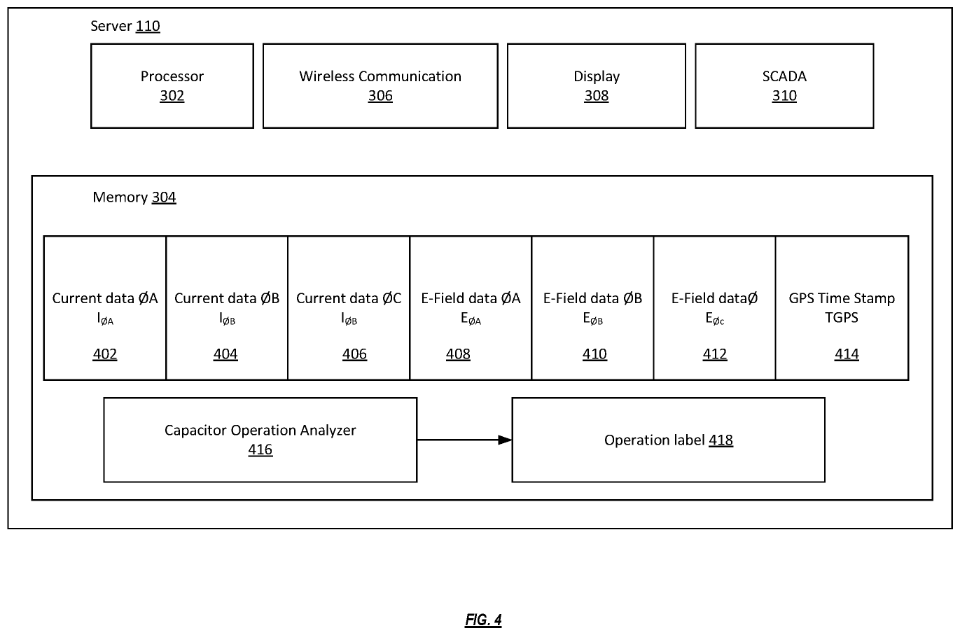

FIG. 4 shows a memory map of the server 110. Processor 302 has an interface and communicates with the wireless communication interface 306 and receives data from the line sensors 106. Processor 302 may control display 308 to display information thereon, and may also communicate with the SCADA 310 systems and deliver operational data to the SCADA 310 as well as respond to control commands therefrom. The processor 302 also interfaces the memory 304 and loads the sensor data received from the line sensors 106 into buffers for the electric field sensors for the three phases, current data for all three phases and time stamps and location for each measurement. As shown in FIG. 4, the current sensor data for phase A are loaded in buffer 402, the current sensor data for phase B are loaded in buffer 404, and the current sensor data for phase C are in buffer 406. Electric field data of phase A are loaded in buffer 408, the electric field data for phase B are loaded in buffer 410, and electric field data for phase C are stored in buffer 412. The GPS data for each data point for current and electric field are stored in buffer 414.

Each buffer 402-414 may contain a series of samples of the waveforms for analysis. Each buffer may also contain preprocessed data to limit the amount of data that needs to be transmitted from the sensors to the back-end server 110. It can also be a series of markers. Although GPS Time Stamp data are shown in a separate buffer the GPS data and Time Stamps can be stored in the same buffer for each value of e-field or current data that is collected. Instead of individual buffers, the data from the line sensors 106 may be stored as a pair of e-field data and current data with the time stamp and GPS data all residing in the same buffer. The data may be operated on as it is received or the server may collect a string of data (e.g., data spanning a period of time) before it processes the string of data.

The data from the line sensors 106, stored in the buffers 402-414, are then processed by a switched-capacitor bank operation analyzer 416. The switched-capacitor operation analyzer 416 may be computer readable instructions that, when executed by the processor 302, operate to analyze the data from the line sensors 106 to determine an operation label 418 (e.g. engaged, or disengaged) of the switched-capacitor bank(s) 108.

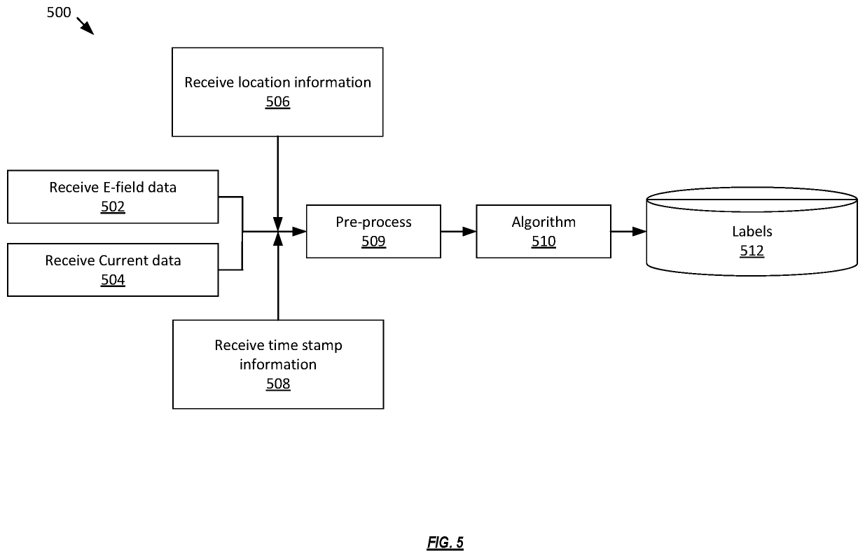

FIG. 5 shows an example process that the server uses to determine the operation of the switched-capacitor bank(s) 108. Process 500 is implemented, for example, via execution of the instructions forming the capacitor operation analyzer 416. The functions of the capacitor operation analyzer 416 can also be performed by the sensors 106 themselves. By transmitting their data to the other sensors 106, one or more of the sensors 106 may include the functionality of the capacitor operation analyzer 416, evaluate the sets of e-field and current data, and determine the state or action of a capacitor bank. Thus, the function of the capacitor operation analyzer 416 can be performed in a distributed processing manner among a set of line sensors 106 and their associated processors 210.

In blocks 502 and 504 of process 500, e-field data is received, and current data is received, respectively. In one example of block 502, the e-field data 214 captured by the line sensors 106 is received at the back-end server 110 (e.g., the e-field data 214) and current data (e.g., the current data 216) are received at a back-end server (e.g., back-end server 110).

In blocks 506 and 508 or process 500, location information and time stamps corresponding to the e-field and current data of blocks 502 and 504 are received. In one example of operation of blocks 506 and 508, the location and time information from positioning interface 202 of each line sensor 106 is received and stored in GPS location and time stamp buffer 414. It should be appreciated that each of blocks 502, 504, 506, and 508 may be performed simultaneously, where each line sensor 106 transmits a string of data to the back-end server 110 (or other of the line sensors 106) including the e-field data, current data, location information, and the time stamp information.

In block 509, each of the e-field data 502, the current data 504, the location information 506, and the time stamp information 508 may be pre-processed. For example, the data may be partitioned into three groups: a pre-disturbance, disturbance, and post-disturbance sections. The term “pre-disturbance section” is also referred to herein as “pre-transient section”. The term “disturbance section” is also referred to herein as “transient section”. The term “post-disturbance section” is also referred to herein as “post-transient section”. In embodiments, the disturbance section is a cycle of the waveform that includes a capacitor-bank switching event, plus and minus a threshold number of cycles. For example, the pre-disturbance section may be defined by the waveform cycles up until a first number of cycles prior to the cycle of a capacitor-bank switching event (also referred to as a “pre-disturbance threshold”). The post-disturbance section may be defined by the waveform cycles after a second number of cycles past the cycle of a capacitor-bank switching event (also referred to as a “post-disturbance threshold”). The disturbance section may be the waveform period between the pre-disturbance threshold and the post-disturbance threshold.

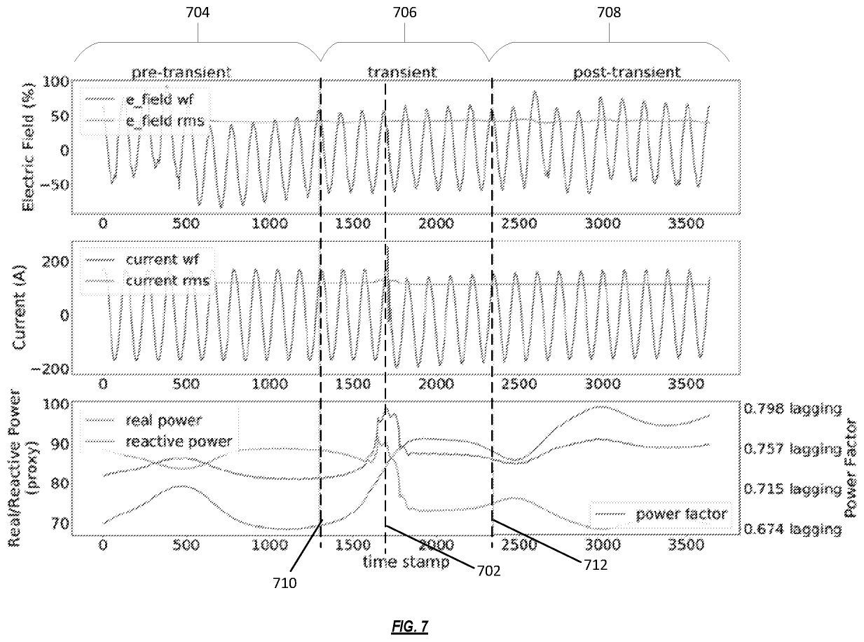

For illustration, in FIG. 7, a capacitor-bank switching event is shown by line 702, with pre-transient section 704, transient section 706, and post-transient section 708. Further shown in FIG. 7, the pre-disturbance threshold 710 may be a different value than the post-disturbance threshold 712. For example, in FIG. 7, the pre-disturbance threshold 710 is three cycles prior to the capacitor-bank switching event 702, and the post-disturbance threshold 712 is five cycles past the capacitor-bank switching event 702.

Block 509 may further include disqualifying certain waveforms received. Since e-field sensors may pick up noise and interference from adjacent conductors and objects, a basic qualification based on the Total Harmonic Distortion (THD) is beneficial. THD may be calculated based on Equation 1, below. Additionally, or alternatively, the standard deviation (STD) of the root mean squared (RMS) version of both e-field and current in the pre- and post-event segments is taken as the qualification criterion as expressed by the following equations.

$${THD}_{E} = \frac{\sqrt{{E}_{2}^{2} + {E}_{3}^{2} + … + {E}_{20}^{2}}}{{E}_{1}} \qquad Equation 1$$

$${STD}_{E} = \sqrt{\frac{1}{N - 1} {\sum }_{i = 1}^{N} ( {RMS}_{E i} - {\overline{RMS}}_{E} )} \qquad Equation 2$$

$${STD}_{I} = \sqrt{\frac{1}{N - 1} {\sum }_{i = 1}^{N} ( {RMS}_{Ii} - {\overline{RMS}}_{I} )} \qquad Equation 3$$

where E represents the e-field RMS, I is the current RMS, Eᵢ is the magnitude of the ith harmonic for the e-field signal, Nis the number of cycles in the pre- or post-transient segment, RMS_{Ei} is the RMS value of the ith cycle in the e-field waveform, RMS_{Ii} is the RMS value of the ith cycle in the current waveform. RMS is the average RMS over N cycles.

The pre-processing block 509 may further implement feature extraction on one or more of the pre-disturbance, disturbance, and post-disturbance sections. Extracted features may include one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power (average, max, min, etc.), e-field real power (Average, max, min, STD), e-field reactive power (Average, max, min, STD), E-I phase (Average, STD), peak counts per cycle, [ΔPQ] to measure the ratio of real and reactive power change (as calculated using equation 4, below), or any combination thereof.

$$Δ PQ = \frac{{P}_{post - transient} - {P}_{pre - transient}}{{Q}_{post - transient} - {Q}_{pre - transient}} \qquad Equation 4$$

In block 510, the process 500 analyzes each of the e-field data 502, the current data 504, the location information 506, and the time stamp information 508, either in raw format or in the pre-processed format after block 509 (e.g., segmented data, or feature-extracted), using a machine learning algorithm to determine operation of the switched capacitor bank(s) 108. The machine learning algorithm may be a classifier that extracts key characteristics (as discussed below) of the e-field and current data, and compares those key characteristics to a library of recorded characteristics used by a predictive model (such as that generated using process 600, as discussed below).

Based on the output of the algorithm analysis in block 510, in block 512, the process 500 outputs labels defining the operational status of one or more switched capacitor banks. In one example of block 512, the operational labels 418 are generated. As discussed above, each line sensor 106 may include a pair of electric field and current sensors on each phase of the power line. In such case, block 510 may be implemented for the electric field and current data from each pair so that a first label, second label, and third label are generated, each of the first phase label, a second phase label, and a third phase label indicating presence of, or lack of, a capacitor switching event on a respective one of the three phases. Block 512 may further include transmitting the operational labels 418 to an external device, such as the SCADA 112 or other device (e.g., mobile device such as a phone, computer, or tablet) used by an operator of the system 100.

In embodiments, process 500 may be initiated actively by the SCADA 112, such as upon a control signal by the SCADA to energize or deenergize a capacitor bank 108. In embodiments, process 500 may be initiated passively, such as by monitoring waveforms generated by the line sensors 106, and reacting to identified transient events therein.

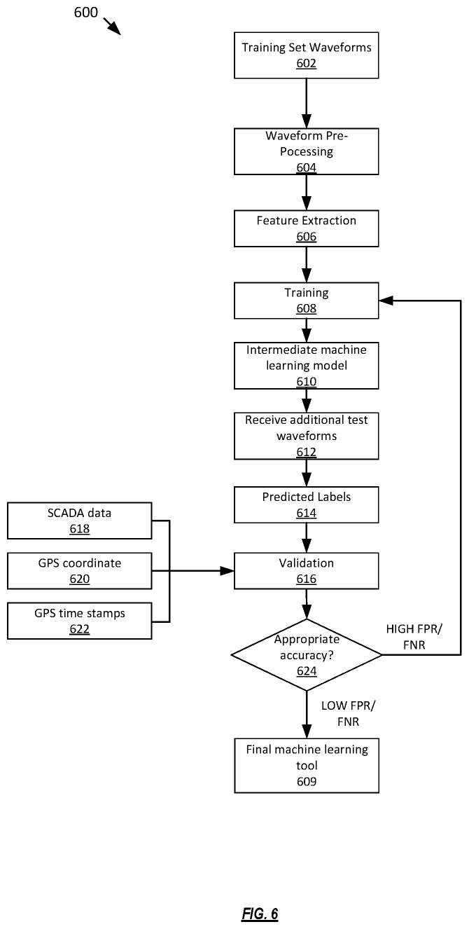

FIG. 6 depicts process 600 for generating the switched-capacitor bank operation classifier used by the switched-capacitor bank operation analyzer 416 of FIG. 4, and block 510 of FIG. 5, in embodiments. Process 600 may be implemented, for example, via execution of the instructions forming the capacitor operation analyzer 416. Alternatively, the process 600 may be implemented external from the capacitor operation analyzer 416, such as in the “cloud” and the output classifier is then transmitted to the capacitor operation analyzer 416.

In block 602, a training set of waveforms is received. In one example of operation of block 602, a set of e-field data (e.g., e-field data 214), and current data (e.g., current data 216) is received by the capacitor operation analyzer 416. In one example of operation, a set of e-field and current data is received from the line sensor(s) 106 including defined operation of the associated switch-capacitor banks 108. The defined operation may be an association by a domain expert and/or the SCADA 112 so that operational status of the switched-capacitor bank 108 may be correlated to one or more captured waveforms by line sensors 106. The association allows for a supervised learning algorithm implemented by process 600. Compared to voltage-based classification approaches, the e-field-based approach requires a higher degree of training data to adequately represent the expected variation in the e-field waveforms across multiple regions and seasons. As discussed above, e-field waveforms are more susceptible to outside forces influencing the generated waveform.

In block 604, process 600 pre-processes the training set received in block 602. In one example of operation of block 604, the e-field and current waveforms are segmented into a pre-disturbance, disturbance, and post-disturbance sections, similar to block 509 discussed above.

Block 604 may further include disqualifying certain waveforms received. Since e-field sensors may pick up noise and interference from adjacent conductors and objects, a basic qualification based on the Total Harmonic Distortion (THD) is beneficial. THD may be calculated based on Equation 1, below. Additionally, or alternatively, the standard deviation (STD) of the root mean squared (RMS) version of both e-field and current in the pre- and post-event segments is taken as the qualification criterion as expressed by equations 1-3, above

Returning to FIG. 6, in block 606, process 600 implements feature extraction on one or more of the pre-disturbance, disturbance, and post-disturbance sections identified in block 604. Extracted features may include one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power (average, max, min, etc.), e-field real power (Average, max, min, STD), e-field reactive power (Average, max, min, STD), E-I phase (Average, STD), peak counts per cycle, [ΔPQ] to measure the ratio of real and reactive power change (as calculated using equation 4, above), and any combination thereof.

TABLE I summarizes potential features, in an embodiment.

TABLE I
Important features for up-stream and down-stream capacitor banks:

| | |
|---|---|
| | Cap bank is downstream of the sensor |
| Pre-transient vs. | Minor e-field rise |
| post-transient | Power factor correction |
| | Minor real power variation |
| | Reactive power reduction |
| | Small ΔPQ changes |
| Transient | Possible inrush current |
| | E-field and current oscillations |
| | Initial e-field drop and current rise |
| | Cap bank is upstream of the sensor |
| Pre-transient vs. | Minor e-field rise |
| post-transient | Power factor remains the same |
| | Minor real power variation |
| | Reactive power remains the same |
| Transient | Possible inrush current |
| | E-field and current oscillations |
| | Initial e-field drop and current drop |

Using the extracted features from block 606, the process 600 trains 608 and outputs 610 an intermediate machine learning model. The intermediate machine learning model maybe based on a variety of machine learning algorithms, including but not limited to: nearest neighbors, support vector machine (SVM), decision tree, random forest, neural net, AdaBoost, quadratic discriminant analysis, and naïve Bayes learning models. In one embodiment of blocks 608 and 610, the intermediate machine learning model output is an AdaBoost classifier with a three-layer decision tree as the base estimator. This configuration of intermediate machine learning model provides a stable and more accurate classifier as compared to other machine learning techniques. For example, Neural Networks may saturate too easily in the downstream waveform calculator where approximately 1 percent of capacitor bank downstream energizing waveforms over the whole waveform set. Furthermore, this configuration reduces false positive rate reduction more than false negative rate. This configuration requires less labeling of the field data (e.g., less confirmation, via human or SCADA implemented, of an actual capacitor bank event correlating to the training waveform). Furthermore, ensemble classifiers, such as AdaBoost utilize voting mechanisms that can better handle cases close to the decision boundary by considering information from multiple weak classifiers.

In block 612, the process 600 receives additional test waveforms. These additional waveforms may be unlabeled e-field and current test data received from the line sensors 106. In block 614, the process 600 applies the intermediate machine learning model 610 to the additional test waveforms from block 612, and outputs predicted labels.

The process 600, in block 616, then compares the predicted labels against received SCADA data 618, location information 620, and time stamps 622 corresponding to the additional test waveforms received in block 612 to verify whether the prediction of block 614 is accurate. In one example of block 616, three conditions need to be satisfied to verify positive labels of the test data: The first condition is that the SCADA timeframe in the SCADA data 618 matches the waveform time stamp. The second condition is that the switched capacitor banks are installed within certain distance (usually <2 km) from the sensor 106 producing the additional test waveform received in block 612. The third condition is that the waveform features sufficiently match the key features identified in the intermediate machine learning model 610. Furthermore, in certain embodiments, since one capacitor bank switching can be detected by multiple sensors, the false negative cases can be determined by time correlating results from the nearby sensors using the true positive cases. The use of GPS chipsets to provide timestamping of the provided data from the line sensors 106 enables the system to have appropriately accurate and synchronized timing data to enable accurate correlation of data from various ones of the line sensors 106.

Block 624 is a decision. In block 624, it is determined whether the intermediate machine learning model is appropriately accurate, e.g., if the false-positive rate (FPR) and false-negative rate (FNR) are adequate based on the validation step 616. The objective of the prediction is to achieve a low false positive rate (FPR) as the first priority and a low false negative rate (FNR) as the second priority. If the prediction results are not satisfactory, process 600 reiterates the training 608 with adjusted training data or training labels. If the prediction results are accurate, process 600 ends by outputting a trained classifier in block 626. The output trained classifier may be used in block 510 to analyze received e-field data 502 and current data 504 to generate labels 512.

The output trained classifier may be transmitted to server 110 (or otherwise stored on if created at server 110) for analysis of received data from line sensors 106 by the capacitor operation analyzer 416. The output trained classifier may include a library of recorded characteristics Furthermore, in embodiments where the line sensors 106 include functionality of the capacitor operation analyzer 416, the output trained classifier may be converted into a different format (e.g., from Python to C programing languages) to allow the line sensors 106, either individually or as a distributed computing system, to implement the machine learning algorithm. In embodiments, the converted format may include one (or more) predictor functions, and a plurality of weak estimator functions, where the probability of each of the predictor function and the weak estimator functions are combined into a capacitor bank event probability, and compared to a probability threshold for a given capacitor bank switching event. If the capacitor bank event probability is above the threshold, then the line sensor 106 (or plurality of line sensors 106) would indicate a capacitor bank switching event.

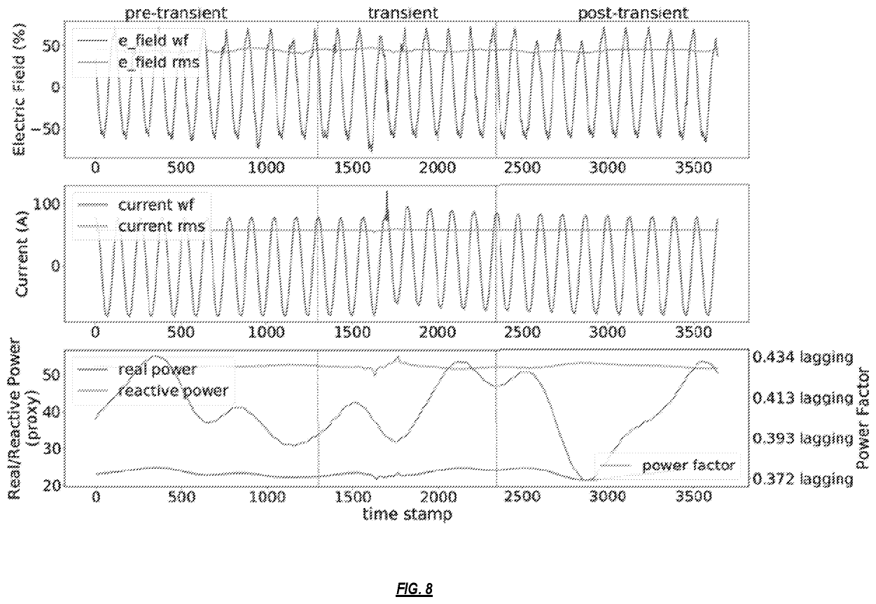

Based on the location of sensors relative to a switched capacitor bank, at least four distinct scenarios are conceivable with respect to a given one of the line sensors 106: energization downstream, energization upstream, de-energization downstream and de-energization upstream. FIG. 7 and FIG. 8 show two example cases of e-field and current waveforms during energization as reported by an upstream sensor and a downstream sensor, respectively. The sampling rate is 7800 samples per cycle. The plots also include the calculated proxy powers (real and reactive), and proxy power factor as individual time series. The term proxy values are used because the exact voltage attributes are not known and for simplicity, the term proxy qualifier is not used in this specification. These measurements come from a large-scale field deployment at a utility in southeast part of the United States. FIG. 7 and FIG. 8 also show the atypical oscillations in the e-field waveforms, highlighting unique challenges for signature characterization. While the subtle correction in the power factor is recognizable in FIG. 7, the same is harder to decipher in FIG. 8. In the former case, the upstream sensor “sees” the reactive power injection from the capacitor bank while in the latter case, the downstream sensor does not “see” the same impact. It is argued that while power factor change is an expected outcome for capacitor banks switching seen by an upstream sensor, it is not an exclusive feature. FIG. 8 shows an example load change waveform that resulted in a similar behavior in the power factor time series, but it is not related to a capacitor bank switching. Therefore, the reactive power or power factor change alone is not an adequate feature for classification.

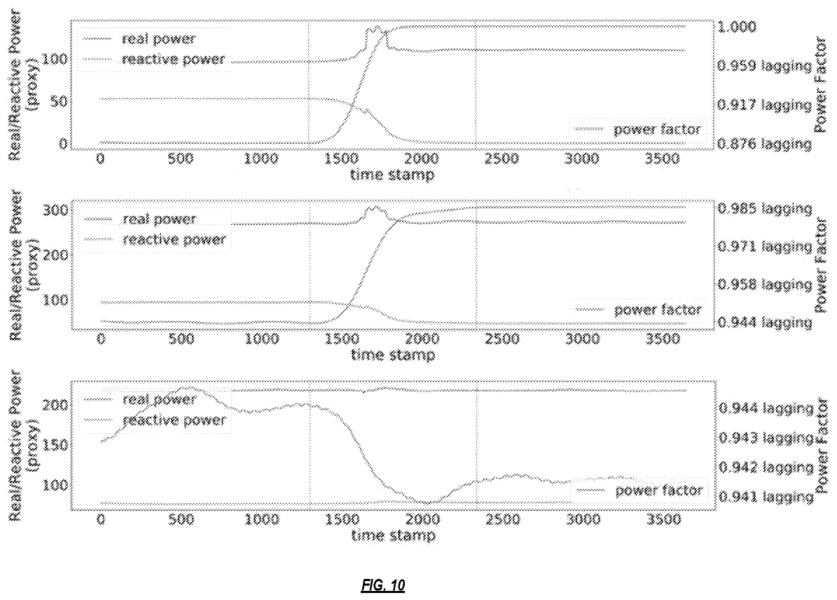

FIG. 10 shows the real/reactive power and power factor of a capacitor bank energization event as captured by three sensors on the same phase. The current and e-field waveforms are similar to those shown in FIG. 7 and FIG. 8.

TABLE II summarizes the notable attributes for these waveforms. ΔP and ΔQ are dimensionless as they are calculated from e-field instead of voltage, yet they are reliable enough to capture the incremental changes in the powers. As the distance to capacitor bank increases (moving from S4 to S3), a) the current and electric field impact is less sensible b) the initial voltage drop becomes smaller, c) ΔP reduces significantly highlighting that the impact of capacitor bank switching is local, and d) ΔQ reduces slightly for downstream capacitor bank.

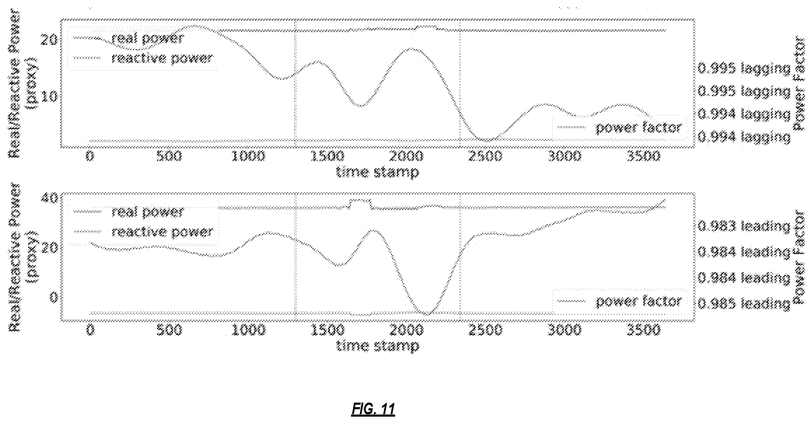

TABLE II
energizing a feeder Capacitor
FIG. 11 shows two sets of real/reactive power and power factor

| | S3 | S4 | S5 |
|---|---|---|---|
| Distance to capacitor bank | 1.48 km | 0.42 km | 1.45 km |
| Relative location | Upstream | Upstream | Downstream |
| ΔP | 1.26 | 12.62 | 0.00 |
| ΔQ | 47.65 | 53.10 | 1.50 |
| Pre pf | 0.944 | 0.877 | 0.944 |
| Post pf | 0.986 | 1.000 | 0.942 |
| Δpf | 0.042 | 0.123 | −0.002 |

graphs from two sensors capturing a substation capacitor bank energization event. TABLE III summarizes the salient metrics calculated for the example shown in FIG. 10. Both downstream sensors are in agreement in terms of the direction of the change but the one closer to the substation sees a much larger impact. In practice, the nature of the loads is also a determining factor so these observations need to be tailored for each specific location and time as would be understood by those of skill in the art.

TABLE III
Energization of a Substation Capacitor

| | S1 | | S2 | |
|---|---|---|---|---|
| Distance to capacitor bank | 0.19 | km | 1.53 | km |
| Relative location | Downstream | | Downstream | |
| ΔP | 0.37 | | 0.13 | |
| ΔQ | 0.12 | | 0.08 | |
| Pre pf | 0.934 | leading | 0.987 | lagging |
| Post pf | 0.942 | leading | 0.987 | lagging |

| | | |
|---|---|---|
| Δpf | −0.008 | 0 |

### Post-Labeling Analysis:

Process 500, discussed above, establishes that a label 512 may be generated to classify events seen in data captured by a line sensor 106, and thereby verify switching operation. However, additional insights and automated control may be gleaned from such label(s), such as, but not limited to: sympathetic capacitor bank switching identification; capacitor bank switching event verification across all three phases; capacitor bank degradation; comparison one or more of individual capacitor bank operation over time; capacitor bank over/under compensation; and similar insights.

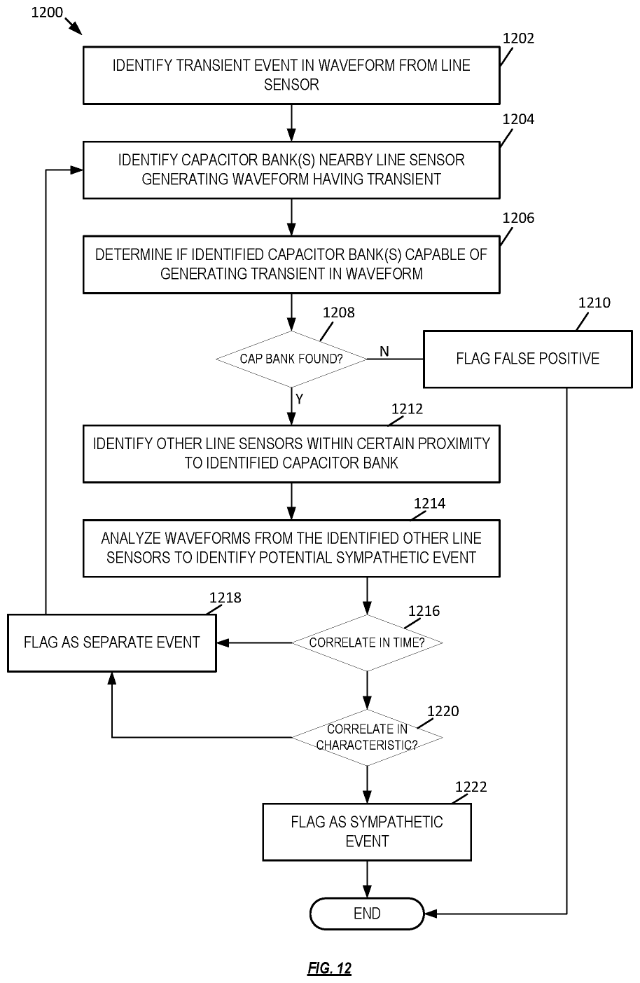

FIG. 12 is a block diagram of process 1200 that identifies sympathetic capacitor switching events, in embodiments. Process 1200 operates to correlate identified capacitor switching events by a plurality of line sensors 106 so that transient events identified across a plurality of line sensors 106 are not redundantly counted. Process 1200 may be implemented by execution, by the processor 302, of the computer readable instructions that implement the switched-capacitor operation analyzer 416 either at the server 110, the SCADA 112, or via distributed logic of the line sensor(s) 106.

In block 1202, method 1200 identifies a transient event in a waveform received at or from a line sensor. In one example of block 1202, a transient event is detected in a waveform formed by one or more of current data 216 and e-field data 214 detected by the line sensor 106. Block 1202 may be implemented by the line sensor 106 itself, or by capacitor operation analyzer 416 of server 110 after receipt of current data 216 and e-field data 214 from the line sensor 106. Method 500 is an example of block 1202.

In block 1204, method 1200 identifies capacitor bank(s) nearby the line sensor that generated the waveform in block 1202. In one example of block 1204, the line sensor 106 that generated the waveform in block 1202, or capacitor operation analyzer 416, receives a list of nearby capacitor banks 108 from the SCADA 112, or pulls a list of nearby capacitor banks from its internal memory.

In block 1206, method 1200 determines if the identified capacitor bank(s) are capable of generating the transient in the waveform of block 1202. In one example of block 1206, the line sensor 106 that generated the waveform in block 1202, or capacitor operation analyzer 416, compares the characteristics of the identified capacitor bank 108 to determine if the capacitor bank is capable of generating the transient when either engaged or disengaged.

Block 1208 is a decision. If none of the identified capacitor banks in block 1204 are capable of generating the transient in the waveform, then process 1200 implements block 1210 and flags the system as a false-positive capacitor event. This false-positive capacitor event in block 1210 may be used by the server 110 to identify other events on the grid. If, in block 1208, a capacitor bank is found that is capable of generating the transient in the waveform in block 1202, then method 1200 implements blocks 1212-1222.

In block 1212, the method 1200 identifies other of the line sensors within certain proximity to the identified capacitor bank. In one example of block 1212, the line sensor 106 that generated the waveform in block 1202, or capacitor operation analyzer 416, receives a list of nearby line sensors 106 from the SCADA 112, or queries a list of nearby line sensors from its internal memory. In one example of operation of block 1212, if line sensor 106(1) generated the waveform including a transient event in block 1202, one or both of line sensors 106(2) and 106(3) are identified in block 1212.

In block 1214, the method 1200 analyzes waveforms from the identified nearby line sensors to identify potential sympathetic transient events. Sympathetic event, as used herein, refers to transient events that correspond to the same capacitor switching event identified in block 1202, but are detected at different locations corresponding to the other identified line sensors.

Block 1216 is a decision. Method 1200 determines if an identified transient event in one of the other line sensors identified in block 1214 correlates in time, based on the location of that other line sensor as identified by the position interface 202 thereof, to the transient event identified in block 1202. If no match is present in block 1216, method 1200 proceeds to block 1218, where the transient event of the given other line sensor is flagged as a separate event, and the method 1200 repeats steps 1204 on for that separate event. If a match is present in block 1216, method proceeds to block 1220.

Block 1220 is a decision. Method 1200 determines if an identified transient event in one of the other line sensors identified in block 1214 correlates in waveform characteristics of the transient event detected by the other line sensor, based on the location of that other line sensor as identified by the position interface 202 thereof and the characteristics of the capacitor bank implementing the switching event, to the transient event identified in block 1202. If no match is present in block 1220, method 1200 proceeds to block 1218, where the transient event of the given other line sensor is flagged as a separate event, and the method 1200 repeats steps 1204 on for that separate event. If a match is present in block 1220, method proceeds to block 1222.

In block 1222, the method 1200 flags the transient event detected by the other line sensor as a sympathetic transient event so that said sympathetic transient event may be disregarded as redundant, or used to verify the transient event detected in block 1202.

Process 1200 illustrates how multiple line sensors 106 may be used by system 100 to verify transient events detected by individual ones of the line sensors 106, and to prevent redundant processing of transient events detected by a plurality of line sensors 106 by grouping multiple of the transient events together as sympathetic transient events. Because of the accuracy and synchronicity of the clocking functions of each of the positioning interfaces 202 at each of the line sensors 106, a single switching event by a capacitor bank 108 may be correlated across multiple line sensors 106.

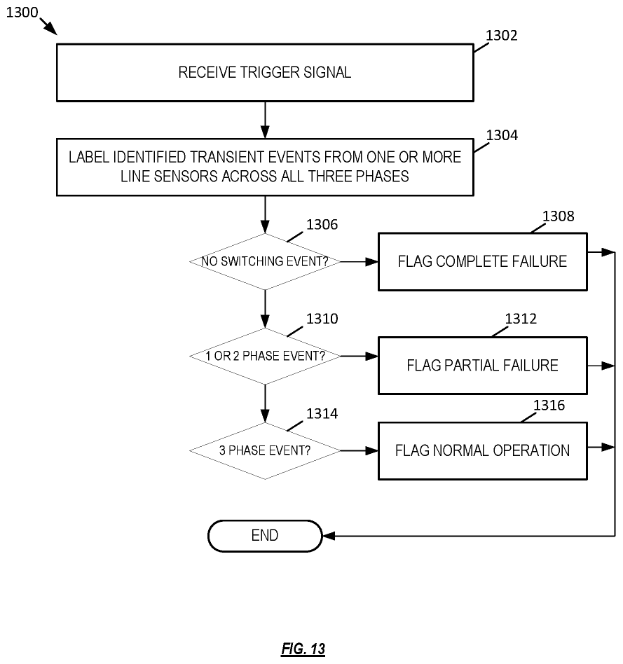

FIG. 13 shows a method 1300 for comparing multiple phases of a single transient event to verify a planned capacitor bank switching event. Method 1300 may be implemented by execution, by the processor 302, of the computer readable instructions that implement the switched-capacitor operation analyzer 416 either at the server 110, the SCADA 112, or via distributed logic of the line sensor(s) 106.

In block 1302, method 1300 receives a trigger. In one example of block 1302, the capacitor operation analyzer 416 receives, from SCADA 112, a trigger signal indicating a planned capacitor switching event. In another example, the trigger is within the detected data from the sensors 106, such as identification of an anomaly in the data.

In block 1304, method 1300 labels identified transient events from one or more line sensors corresponding to the planned capacitor switching event. Method 500 is an example of block 1304. The labels may label the capacitor switching event for a given capacitor bank 108 for each individual phase. Each label may be obtained based on data from a single one of the line sensors 106, or from multiple ones of the line sensors 106. This allows for the system and associated logic to accommodate malfunctioning sensors, where a given one of the line sensors 106 is not working for a given phase, then another of the line sensors may be able to detect a waveform that allows identification of the switching event on the phase with the malfunctioning sensor.

Block 1306 is a decision. If in block 1306, method 1300 identifies that no switching event was found in the data from the one or more line sensors, then the method proceeds with block 1308. At block 1308, method 1300 flags a complete failure. The complete failure flag may be transmitted to the SCADA 112, or to an operator device such that the capacitor bank may be inspected. Alternatively, the complete failure flag may initiate an automatic re-initiation of the planned switching event corresponding to the trigger signal from block 1302 so that the capacitor bank may be re-engaged or re-disengaged in case the initial planned switching event did not occur as planned.

Block 1310 is a decision. If in block 1310, method 1300 identifies that a switching event was found in the data from the one or more line sensors, but only on 1 or two of the phases when all three phases should have indicated a switching event, then the method proceeds with block 1312. At block 1312, method 1300 flags a partial failure. The partial failure flag may be transmitted to the SCADA 112, or to an operator device such that the capacitor bank may be inspected. Alternatively, the complete partial flag may initiate an automatic re-initiation of the planned switching event corresponding to the trigger signal from block 1302 so that the capacitor bank may be re-engaged or re-disengaged across all three phases if possible.

Block 1314 is a decision. If in block 1314, method 1300 identifies that a switching event was found in the data from the one or more line sensors and across all three phases, then the method proceeds with block 1316. Alternatively, or additionally, block 1314 may identify a purposefully created variance across the phases, and output normal operation when the detected variance from the data provided by the line sensor(s) 106 matches the intended variance. For example, if Phase A is intended to have a larger reactive power compensation than Phase C due to different operating conditions, a normal operation flag may be set if the line sensor data may indicate such variance in reactive power compensation within a pre-defined tolerance threshold. At block 1316, method 1300 flags normal operation (i.e., successful switching event). The partial normal operation flag may be transmitted to the SCADA 112, or to an operator device such the system 100 may have knowledge of the successful switching event.

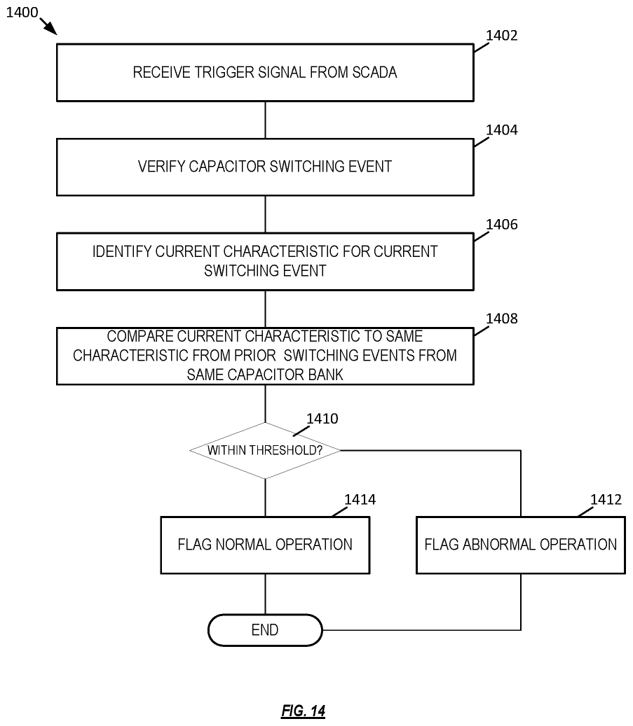

FIG. 14 depicts a method 1400 for monitoring and managing historical operation of switched-capacitor banks in a grid, in embodiments. Method 1400 may be implemented by execution, by the processor 302, of the computer readable instructions that implement the switched-capacitor operation analyzer 416 either at the server 110, the SCADA 112, or via distributed logic of the line sensor(s) 106.

In block 1402, method 1400 receives a trigger from the SCADA. In one example of block 1402, the capacitor operation analyzer 416 receives, from SCADA 112, a trigger signal indicating a planned capacitor switching event.

In block 1404, method 1300 verifies identified capacitor switching event from one or more line sensors corresponding to the planned capacitor switching event. Methods 500 and/or 1300 is an example of block 1404.

In block 1406, the method 1400 extracts and/or identifies one or more characteristic of the waveform corresponding to the verified capacitor switching event. In one example of block 1406, the method 1400 identifies the reactive power across one or more of the phases. In another or an additional example, the method 1400 identifies whether the capacitor bank is over or under compensated.

In block 1408, the method 1400 compares the identified one or more characteristic from block 1406 to prior history of the one or more characteristic from the same capacitor bank. For example, the method 1400 may determine if the reactive power is degraded over a period of time. As another example, the method 1400 may determine if the capacitor bank is over or under compensated for a period of time.

Block 1410 is a decision. If the comparison of the current to prior characteristics of the transient event from the capacitor bank of over a threshold, or occurs for a threshold amount of time, then method 1400 proceeds with block 1412 and flags abnormal operation of the capacitor bank (such as degraded capacitor bank, or over/under compensating capacitor bank). Else, method 1400 proceeds with block 1414 and outputs a normal operation flag.

The comparison of the current characteristic to the characteristic from prior switching events in blocks 1406 and 1408 may include logging the current and prior characteristics as a switching event characteristic count. The threshold decision of block 1410 may then analyze whether the count is above or below a predetermined threshold. For example, the characteristic may be a binary successful or unsuccessful identification of the capacitor switching event. The threshold may compare the count and determine the operation of the capacitor bank. For example, if a capacitor bank is energizing 300 times a month, this may be deemed as excessive (e.g., it is only supposed to energize 200 times a month). Thus, the threshold of block 1410 is a percentage above (or below) of counts of intended capacitor switching events over a given time period (e.g., one month). Further, if a given phase is energizing twice per month, but the other phases are energizing 25 and 30 times a month, respectively, this indicates improper operation of the capacitor bank with respect to the phase energizing only twice per month. Thus, the threshold is a comparison of energizing or deenergizing capacitor switching events on one or two phases compared to another phase.

### Combination of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:

(A1) In an embodiment of a first aspect, a system for automated detection of switched-capacitor bank operation on a power grid includes: a power line sensor positioned on a power line to measure electric field strength and current; a processor in communication with the power line sensor; and memory storing a capacitor bank analyzer as computer readable instructions. When the capacitor bank analyzer is executed by the processor, the processor is controlled to: receive electric field data and current data from the power line sensor; extract key characteristics from the electric field data and the current data; compare the key characteristics to a library of key characteristics of a predictive model; and output, based on the predictive model, a label indicating presence of, or lack of, a capacitor switching event.

(A2) In the embodiment (A1), the label indicates capacitor bank engaging with the power grid.

(A3) In either embodiment (A1)-(A2), the label indicates capacitor bank engaging with the power grid.

(A4) In any embodiment (A1)-(A3), the label indicating capacitor bank dis-engaging with the power grid.

(A5) In any embodiment (A1)-(A4), the power line sensor including a positioning interface.

(A6) In any embodiment (A5), the system further including additional computer readable instructions that, when executed by the processor, control the processor to associate location information and time stamps to the received electric field data and the received current data.

(A7) In any embodiment (A1)-(A6), the power line sensor including three pairs of electric field sensors and current sensors, each pair located on one of three phases of the power line.

(A8) In any embodiment (A7), the instructions to compare the key characteristics to a library of key characteristics including instructions that that, when executed by the processor, control the processor to compare, for each of the three phases, the electric field and current data from the respective pair of electric field sensors and current sensors, and the instructions to output the label including instructions that, when executed by the processor, control the processor to output a first phase label, a second phase label, and a third phase label, each of the first phase label, a second phase label, and a third phase label indicating presence of, or lack of, a capacitor switching event on a respective one of the three phases.

(A9) In any embodiment (A1)-(A8), the key characteristics including one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power, e-field real power, e-field reactive power, E-I phase, peak counts per cycle, ΔPQ, and any combination thereof.

(A10) In any embodiment (A1)-(A9), the processor and memory being located at the power line sensor.

(A11) In any embodiment (A1)-(A10), the capacitor bank analyzer initiating in response to receipt, from a SCADA associated with the power grid, of indication of a control signal to energize or deenergize the capacitor bank.

(A12) In any embodiment (A1)-(A11), the capacitor bank analyzer including further instructions that, when executed by the processor, control the processor to: log in the memory, based on the label and historical labels generated by the capacitor bank analyzer, switching event count; and output an improper operation signal when the switching event count breaches a predefined threshold.

(A13) In any embodiment (A12), the threshold being a number or percentage of successful switching events of the capacitor bank over a predefined period.

(A14) In any embodiment (A1)-(A13), the capacitor bank analyzer including further instructions that, when executed by the processor, control the processor to: log in the memory, the key characteristics of the received e-field and current data; and, compare at least one current key characteristic to prior key characteristics; and output a capacitor bank degradation signal when the current key characteristic differs from prior key characteristics by a predetermined threshold.

(A15) In any of the embodiments of (A1)-(A14), the system further including any of the features described in the embodiments of the second and third aspect provided below and/or the features of the systems and methods described herein.

(B1) In an embodiment of a second aspect, a method for verifying the operation of capacitor bank on a power line includes: sensing, using a power line sensor, current and electric field on a power line; recording a transient waveform based on the sensed current and electric field; determining key characteristics of waveform; comparing the key characteristics with a library of recorded characteristics to generate a label of a transient event within the transient waveform; and outputting the label.

(B2) In the embodiment (B1), the method further including attaching location and time information, captured by a positioning interface at the power line sensor, to the electric field and current data.

(B3) In any embodiment (B2), the method further including preprocessing the transient waveform into a pre-disturbance section, a disturbance section, and a post-disturbance section; wherein the determining key characteristics of the waveform including determining key characteristics for each of the pre-disturbance section, the disturbance section, and the post-disturbance section; and wherein the comparing the key characteristics includes comparing the key characteristics for each of the pre-disturbance section, the disturbance section, and the post-disturbance section against the library of recorded characteristics.

(B4) In any embodiment (B1)-(B3), the method further including preprocessing the transient waveform into a pre-disturbance section, a disturbance section, and a post-disturbance section; and disqualifying one or more transient waveforms based on one or more of total harmonic distortion, standard deviation of the root mean squared version of e-field in the pre-disturbance section and the post-disturbance section of the respective transient waveform, and standard deviation of the cycle-to-cycle root mean squared version of the current in the pre-disturbance section and the post-disturbance section of the respective transient waveform.

(B5) In any embodiment (B1)-(B4), the key characteristics including one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power, e-field real power, e-field reactive power, E-I phase, peak counts per cycle, ΔPQ, and any combination thereof.

(B6) In any embodiment (B1)-(B5), the method initiating in response to receipt, from a SCADA associated with the power grid, of indication of a control signal to energize or deenergize the capacitor bank.

(B7) In any of the embodiments of (B1)-(B6), the method further including any of the features described in the embodiments of the first aspect provided above and third aspect provided below and/or the features of the systems and methods described herein.

(C1) In an embodiment of a third aspect, method for correlating sensed capacitor bank switching events by a plurality of line sensors, including: labeling a transient event in a waveform sensed by a first line sensor of the plurality of line sensors; determine if at least one capacitor bank nearby the first line sensor is capable of producing the transient event; and when at least one capacitor bank is nearby the first line sensor identify at least one other line sensor of the plurality of line sensors within a proximity to the at least one capacitor; for each other line sensor: analyze another waveform received by the other line sensor, to identify a potential sympathetic event, and flag the potential sympathetic event as a sympathetic event when the potential sympathetic event correlates to the transient event.

(C2) In the embodiment (C1), wherein the potential sympathetic event correlates to the transient event when the timestamps in the waveforms from the first line sensor and the other line sensor correlate to each other.

(C3) In any embodiment (C1)-(C2), wherein the potential sympathetic event correlates to the transient event when the characteristics in the waveforms from the first line sensor and the other line sensor correlate to each other.

(C4) In any embodiment (C1)-(C3), the waveform and the another being based on e-field data from the first line sensor and other line sensor, respectively.

(C5) In any embodiment (C4), the waveform and another waveform being further based on current data from the first line sensor and other line sensor, respectively.

(C6) In any embodiment (C1)-(C5), when the at least one capacitor bank is not determined, flag the transient event as a false positive.

(C7) In any embodiment (C1)-(C6), the method further including flag the potential sympathetic event as a separate event when the potential sympathetic event does not correlate to the transient event.

(C8) In any embodiment (C6), the method further including repeating the steps of determine, analyze, and flag for the separate event.

(C9) In any of the embodiments of (C1)-(C8), the method further including any of the features described in the embodiments of the first aspect and the second provided above and/or the features of the systems and methods described herein.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A system for automated detection of switched-capacitor bank operation on a power grid comprising:
a power line sensor positioned on a power line to measure electric field strength and current;
a processor in communication with the power line sensor;
memory storing a capacitor bank analyzer as computer readable instructions that, when executed by the processor, control the processor to:
receive electric field data and current data from the power line sensor,
extract key characteristics from the electric field data and the current data,
compare the key characteristics to a library of key characteristics of a predictive model,
output, based on the predictive model, a label indicating presence of, or lack of, a capacitor switching event.

2. The system of claim 1, the label indicating capacitor bank engaging with the power grid.

3. The system of claim 1, the label indicating capacitor bank dis-engaging with the power grid.

4. The system of claim 1, the power line sensor including a positioning interface.

5. The system of claim 4, further comprising additional computer readable instructions that, when executed by the processor, control the processor to associate location information and time stamps to the received electric field data and the received current data.

6. The system of claim 1, the power line sensor including three pairs of electric field sensors and current sensors, each pair located on one of three phases of the power line.

7. The system of claim 6,
the instructions to compare the key characteristics to a library of key characteristics including instructions that that, when executed by the processor, control the processor to compare, for each of the three phases, the electric field and current data from the respective pair of electric field sensors and current sensors, and
the instructions to output the label including instructions that, when executed by the processor, control the processor to output a first phase label, a second phase label, and a third phase label, each of the first phase label, a second phase label, and a third phase label indicating presence of, or lack of, a capacitor switching event on a respective one of the three phases.

8. The system of claim 1, the key characteristics including one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power, e-field real power, e-field reactive power, E-I phase, peak counts per cycle, and ΔPQ.

9. The system of claim 1, the processor and memory being located at the power line sensor.

10. The system of claim 1, the capacitor bank analyzer initiating in response to receipt, from a SCADA associated with the power grid, of indication of a control signal to energize or deenergize the capacitor bank.

11. The system of claim 1, the capacitor bank analyzer including further instructions that, when executed by the processor, control the processor to:
log in the memory, based on the label and historical labels generated by the capacitor bank analyzer, switching event count; and
output an improper operation signal when the switching event count breaches a predefined threshold.

12. The system of claim 11, the threshold being a number or percentage of successful switching events of the capacitor bank over a predefined period.

13. The system of claim 1, the capacitor bank analyzer including further instructions that, when executed by the processor, control the processor to:
log in the memory, the key characteristics of the received e-field and current data; and,
compare at least one current key characteristic to prior key characteristics; and
output a capacitor bank degradation signal when the current key characteristic differs from prior key characteristics by a predetermined threshold.

14. A method for verifying the operation of capacitor bank on a power line comprising:
sensing, using a power line sensor, current and electric field on a power line;
recording a transient waveform based on the sensed current and electric field;
determining key characteristics of waveform;
comparing the key characteristics with a library of recorded characteristics to generate a label of a transient event within the transient waveform; and
outputting the label.

15. The method of claim 14, further comprising attaching location and time information, captured by a positioning interface at the power line sensor, to the electric field and current data.

16. The method of claim 15, further comprising preprocessing the transient waveform into a pre-disturbance section, a disturbance section, and a post-disturbance section;
wherein the determining key characteristics of the waveform including determining key characteristics for each of the pre-disturbance section, the disturbance section, and the post-disturbance section; and
wherein the comparing the key characteristics includes comparing the key characteristics for each of the pre-disturbance section, the disturbance section, and the post-disturbance section against the library of recorded characteristics.

17. The method of claim 14, further comprising preprocessing the transient waveform into a pre-disturbance section, a disturbance section, and a post-disturbance section; and
disqualifying one or more transient waveforms based on one or more of total harmonic distortion, standard deviation of the cycle-to-cycle root mean squared version of e-field in the pre-disturbance section and the post-disturbance section of the respective transient waveform, and standard deviation of the cycle-to-cycle root mean squared version of the current in the pre-disturbance section and the post-disturbance section of the respective transient waveform.

18. The method of claim 17, the key characteristics including one or more of: e-field rise, e-field drop, current rise, current drop, power factor correction, real-power variation, reactive power reduction, reactive power increase, ΔPQ change, inrush current, e-field oscillation, current oscillation, e-field drop, current rise, e-field RMS, E-field STD, Current RMS, Current STD, e-field apparent power, e-field real power, e-field reactive power, E-I phase, peak counts per cycle, and ΔPQ.

19. The method of claim 14, the method initiating in response to receipt, from a SCADA associated with the power grid, of indication of a control signal to energize or deenergize the capacitor bank.

20. A method for correlating sensed capacitor bank switching events by a plurality of line sensors, comprising:
labeling a transient event in a waveform sensed by a first line sensor of the plurality of line sensors;
determine if at least one capacitor bank nearby the first line sensor is capable of producing the transient event; and
when at least one capacitor bank is nearby the first line sensor identify at least one other line sensor of the plurality of line sensors within a proximity to the at least one capacitor;
for each other line sensor:
analyze another waveform received by the other line sensor, to identify a potential sympathetic event, and
flag the potential sympathetic event as a sympathetic event when the potential sympathetic event correlates to the transient event.

21. The method of claim 20, wherein the potential sympathetic event correlates to the transient event when the timestamps in the waveforms from the first line sensor and the other line sensor correlate to each other.

22. The method of claim 20, wherein the potential sympathetic event correlates to the transient event when the characteristics in the waveforms from the first line sensor and the other line sensor correlate to each other.

23. The method of claim 20, the waveform and the another being based on e-field data from the first line sensor and other line sensor, respectively.

24. The method of claim 23, the waveform and the another waveform being further based on current data from the first line sensor and other line sensor, respectively.

25. The method of claim 20, when the at least one capacitor bank is not determined, flag the transient event as a false positive.

26. The method of claim 20, further comprising flag the potential sympathetic event as a separate event when the potential sympathetic event does not correlate to the transient event.

27. The method of claim 26, further comprising repeating the steps of determine, analyze, and flag for the separate event.
